(19) United States
(12) Patent Application Publication
(10) Pub. No.: US 2006/0220498 A1
(43) Pub. Date: Oct. 5, 2006

(54) Method for determining at least one state parameter of a sealing system and sealing system

(75) Inventor: Friedrich Kremer, Markkleeberg (DE)

Correspondence Address: ROTHWELL, FIGG, ERNST & MANBECK, P.C., 1425 K STREET, N.W., SUITE 800, WASHINGTON, DC, 20005, US

(73) Assignee: UNIVERSITAET LEIPZIG, LEIPZIG (DE)

(21) Appl. No.: 10/544,765

(22) PCT Filed: Feb. 5, 2004
(86) PCT No.: PCT/EP04/01080

§ 371 Date: Mar. 1, 2006

(30) Foreign Application Priority Data
Feb. 7, 2003 (DE) 103 05 110.4
Sep. 19, 2003 (DE) 103 43 498.4

(51) Int. Cl. H01L 41/00

(52) U.S. Cl. 310/338; 310/340

(57) ABSTRACT

The invention relates to a method for determining at least one state parameter of a sealing system (10, 110) comprising at least one sealing element (12, 112) and at least one dielectric element (24, 124) containing dielectric material (26, 126). The invention is characterised in that the real part and/or the imaginary part of the complex, dielectric function of the dielectric element is measured.

The invention relates to a method for determining at least one state parameter of a sealing system having at least one dielectric element containing dielectric material, as well as a sealing system.

Sealing systems are used in many different applications to seal two spaces from one another (for example sealing a container or a pipe toward the outside), with the sealing system having the function of preventing a transfer of fluid (either in gaseous or liquid form) from one space to the other.

Extremely high requirements are placed on the dependability of these sealing systems, for example in the construction of chemical facilities or in nuclear power plants. A dependable sealing is not only important immediately following assembly, but also over the course of optimally long periods of operation. The sealing elements may be subjected to high pressure which may even fluctuate, with temperature stresses being an additional factor. The action of the fluid to be sealed may also lead to changes in the structure and chemical composition of the sealing material. These influences generally lead to an impairment of the sealing function of the sealing material, which could also be called an additional ageing of the sealing material in addition to the natural ageing of the sealing material. Because it was not practically possible to record the ageing of the sealing material to date, the sealing elements—at least those with high requirements as to the dependability of the sealing—have to be replaced in relatively short time intervals. Because of the resulting downtime of the facility during the replacement of the sealing, this can lead to significant economical losses.

Methods for monitoring sealing systems are known. For example, DE 30 06 656 A1 describes a flat gasket that is arranged between two flanges and simultaneously acts as a pressure transmitter. A dielectric is arranged between two electrode layers. The electrodes are connected to a measuring device. If the flanges are moved toward one another to achieve the sealing function, the resulting volume deformation of the dielectric will lead to electrostatic surface charges that are discharged by the electrodes and send a signal corresponding to the sealing pressure after amplification by an amplifier.

DE 41 01 871 A1 discloses a sealing system where a sensor film, which is comprised of a flexible piezoelectric layer between two protective layers, is installed in the sealing element. The piezoelectric voltage can be used to determine the mechanical tension condition within the sealing element, even over longer operating periods. A decrease in the sealing pressure measured in this way indicates the degree of ageing of the sealing material, but this presupposes that the tensile force acting on the flanges remained unchanged. This printed specification specifically rejects the notion of recording the sealing pressure by using the change in the capacity of the pressurized capacitors with electrically deformable dielectrics because in this sealing principle, the request for elastic deformation contradicts the request for a visco-elastic flow behavior. Thus, the part of the change in capacity which is attributable to the plastic deformation and thus the sealing pressure is generally superimposed to an unknown extent by the change in capacity that is attributable to the visco-elastic flow. The measuring accuracy would be significantly limited in particular for smaller seals.

For the monitoring of the seal tightness of piping, it is known (DE 34 41 924 A1) to wrap them with a leak indicator cable which has a porous PTFE band as a detector layer between two electrode layers, with a change of capacity in this arrangement indicating the penetration of leakage fluid.

DE 41 39 602 A1 discloses a method for determining electromagnetic impedances in a frequency range between 0 Hz and 10 GHz, which can be used to determine dielectric and magnetic material parameters.

EP 0 841 516 A1 discloses a method for determining leakages in a sealing system having at least one sealing element and at least one dielectric element, where a change of the resonant oscillations of a parallel resonance circuit is verified as a result of a change of the dielectric constant in the area of the sealing system.

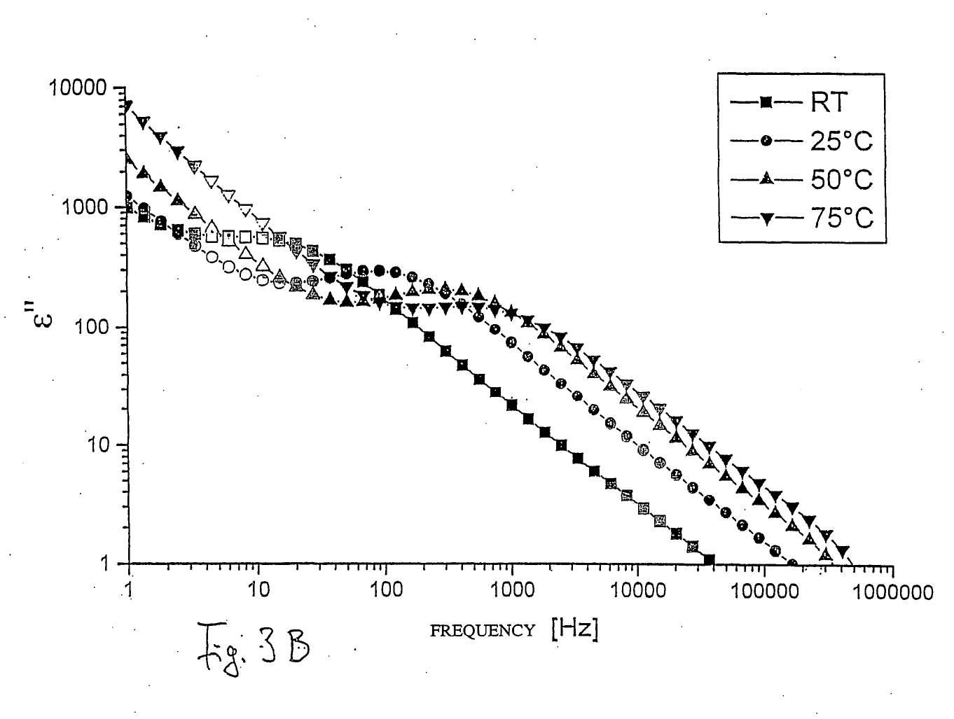

U.S. Pat. No. 5,072,190 A shows in connection with a pressure sensor housing how, among other things, the density of the pressure sensor housing is checked by monitoring the electrical properties of a pressure transmission fluid filled into the housing (see FIG. 2 with related description). The electrical resistance or the conductivity is cited as examples of the electrical properties of the pressure transmission fluid which are to be monitored.

The invention was based on the problem of providing a method for determining at least one state parameter of a sealing system which allows dependable statements concerning the state of the sealing system.

The object of the invention is attained in that the real part and/or the imaginary part of the complex dielectric function of the dielectric element are measured preferably with at least one frequency >0.01 Hz.

It was found that using measuring technology to record the dielectric function can provide a wealth of information concerning the internal state of the sealing system. For example, the dielectric function can be recorded across an extremely broad frequency range of 10⁻⁶ to 10⁷ Hz with measuring techniques, with the real part and the imaginary part of the dielectric function allowing varying conclusions concerning the state of the dielectric. An overview of the measuring procedures that can be applied is found in the textbook “Broadband Dielectric Spectroscopy” by F. Kremer, A. Schonhals, published by Springer Verlag, Berlin in 2002, specifically in chapter 2, “Broadband dielectric measurement techniques.”

Depending on the dielectric material being used, statements concerning the interior state of mechanical tension of the dielectric material can be made so that, for example, a skewed assembly position of the sealing system can be determined through several dielectric elements distributed across the periphery. Conclusions can also be drawn concerning the interior structural and molecular setup of the dielectric element, which also depends on the ageing condition of the dielectric material. If the dielectric material used for the dielectric element is the same as the dielectric material used for the actual sealing element, it is therefore possible to record the ageing condition of the sealing element.

Furthermore, there is the possibility of monitoring the tightness of the sealing system directly by using a type of dielectric material for the dielectric element which changes its dielectric properties when it comes into contact with the fluid to be sealed. Preferably, an appropriately porous dielectric material is used, with a high capillarity for the fluid being used.

The frequency range for the measurement of the dielectric function is determined depending on the dielectric material being used, i.e., such that the sensitivity of the real part and/or the imaginary part of the dielectric function is highest for the state parameter that is of interest. Generally, the frequency will be in a frequency range between 0.1 Hz to 10 MHz, preferably between 100 Hz and 100 kHz. Lower frequencies lead to problems due to the occurrence of ionic charge carrier transport. Higher frequencies are principally measurable, but with a different type of energy coupling.

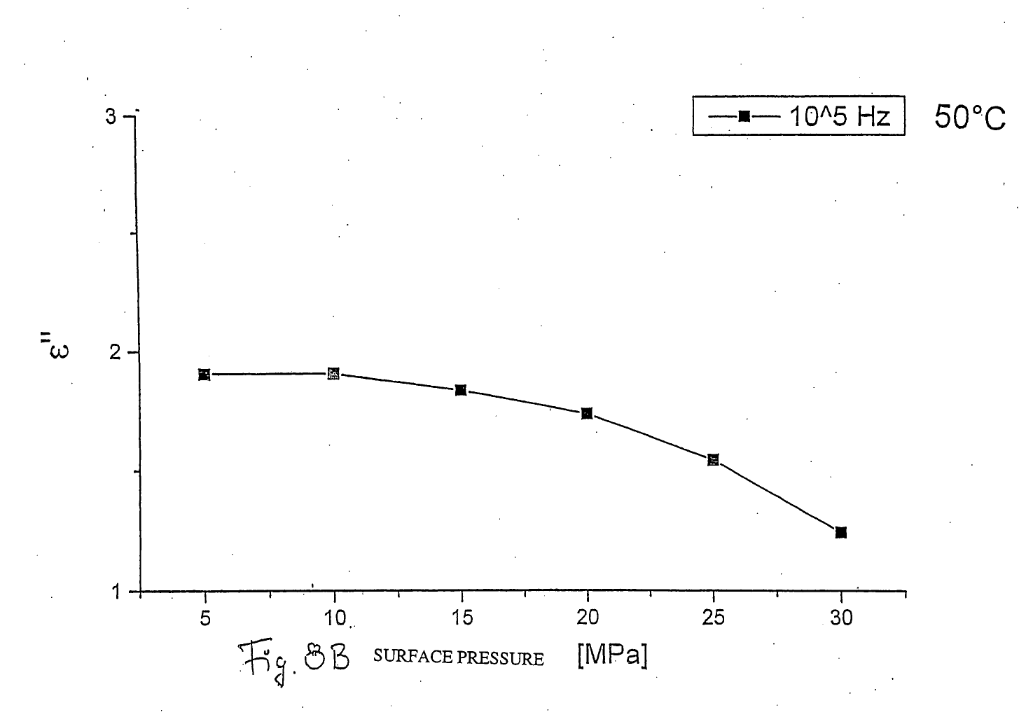

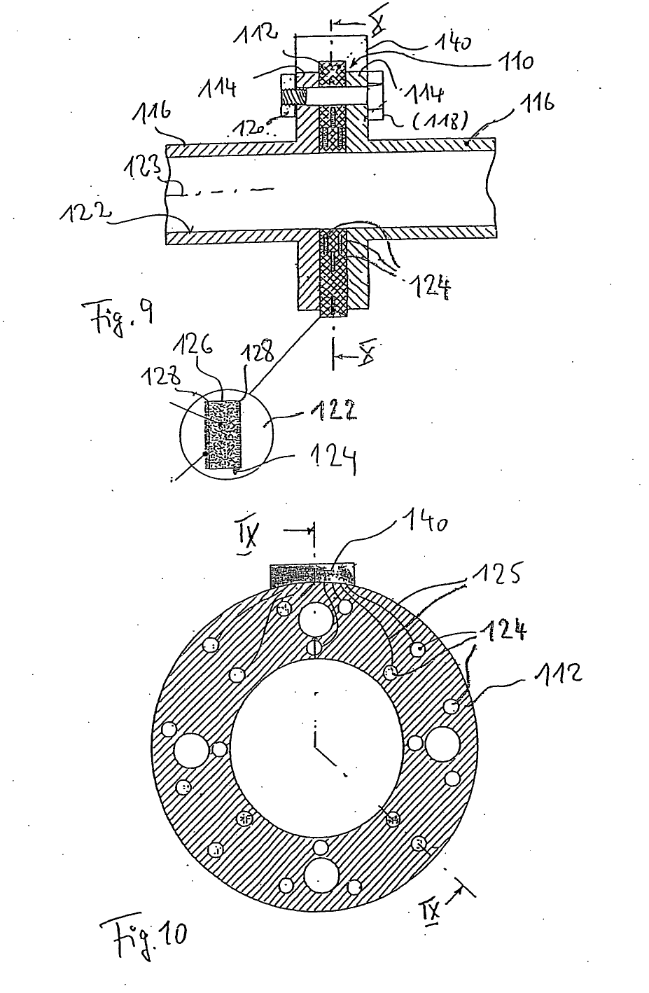

Preferably, a characteristic frequency curve of the real part and/or the imaginary part of the dielectric function is determined. In many cases, preliminary measurements with the intended dielectric material will show which frequency range for the frequency response curve of the real part and/or for the frequency response curve of the imaginary part reacts most sensitively to changes of the state parameter that is of interest. Generally, the complex dielectric function is determined by charge transfers and by molecular relaxation processes. The charge transfer by ions is indicated by an increase of the real part (also called ε′) and the imaginary part (also called ε″) with decreasing frequency. Molecular relaxation processes, however, are expressed in a peak in ε″ and in a stage in ε′ (see also, for example, Kohlrausch “Praktische Physik” [Practical Physics], published by Teubner Publishing, Stuttgart, 1985, Volume II, page 866, FIG. 10.115, with the example of vulcanized hard rubber).

Therefore, depending on the dielectric material that is being used, one would appropriately select form parameters of the frequency response curve such as absolute value, slope or curvature of the frequency response curve at a given frequency. However, it is also possible to use the frequency position or the amplitude of a characteristic segment of the frequency response curve, such as a stage or a peak, as form parameter.

The dependability of determining a state parameter such as, for example, the ageing of the sealing material of the dielectric system, can be increased significantly by observing a plurality of form parameters. With dielectric material made of aromatic polyamide fibers (such as aramide fibers) embedded in nitrile rubber, the following combination has proven useful: First form parameter: slope of the real part at lower frequencies, preferably <100 Hz; second and third form parameter: absolute values of the real part and the imaginary part at high frequencies, preferably >1 kHz. With a dielectric material containing PTFE (polytetrafluoroethylene), such as material of aramide fibers impregnated with a PTFE dispersion, the absolute value of the imaginary part at a frequency between 100 Hz and approximately 1 kHz, preferably of approximately 100 Hz, has proven useful as form parameter.

In the case that the frequency response curve of ε″ has a peak, as is the case with the vulcanized hard rubber discussed earlier, it is also possible to use the surface area formed below the peak (also called dielectric loss) as form parameter. Another example of a possible form parameter is the quotient from the absolute values of the imaginary part and the real part (also called loss factor tanδ with δ=loss angle).

The preliminary measurements on the respective material will determine which form parameter and/or which combination of form parameters will be the appropriate ones to select.

Preferably, dielectric elements are provided at a plurality of places on the sealing element, and the respective real part and/or the imaginary part of the dielectric function is measured on said sealing elements. This increases the reliability of the method because several respective measuring results are available. If one dielectric element fails, the state of the sealing system can also be determined using the remaining dielectric elements.

In addition, this type of arrangement with a plurality of dielectric elements distributed across the periphery of the sealing element provides the option of determining the proper assembly position of the sealing system. If the assembly position is skewed, the dielectric elements are pressed together accordingly with varying pressure, which has a corresponding effect on the respective complex dielectric function. Thus, if in a comparison of the measuring results obtained at various places, the deviations of the measuring results relative to one another exceed a given measure, it can be assumed that the assembly position of the sealing system is skewed. Said given measure would again be determined in advance with appropriate comparison measurements. Preferably, a respective form parameter that is specific for changes in the mechanical tension of the material will be determined to compare the measuring results. In the example discussed earlier, i.e., with dielectric material of aramide fiber within a PTFE dispersion, the absolute value of ε″ proved efficient as a form parameter at approximately 100 Hz.

To check whether the current sealing element in the assembly is functioning properly, it is recommended to compare the current measuring result on said sealing element to a reference measurement on a properly functioning sealing element which, if the current measurement exceeds or falls below the given measurement of a given limit value, leads to the conclusion that the current sealing element is not functioning properly. In this case, the state parameter may be at least one of the state parameters already mentioned earlier, i.e. sealing pressure, ageing or seal tightness. A potential reference measurement would be a measurement performed earlier on the same dielectric material, so as to be able to check whether the seal designated for the assembly is new or already aged. Generally, however, the first measurement taken after the assembly would be used as the reference measurement, and it would be compared to the measurements obtained in the ongoing monitoring of the sealing system.

The decision whether or not the current sealing element is still operationally reliable is performed with the given measure for the still acceptable deviation and/or based on the given limit value. Both values can be determined in advance by using appropriate measurements after stress test measurements on the subject sealing system. For the state parameter that indicates the ageing condition, intermediate sample heating steps would be inserted to obtain a “time lapse” ageing. If the state parameter is supposed to indicate the seal tightness of the sealing system, it is preferable to perform a stress testing series with increasing fluid pressure until leakage occurs.

The dielectric element may form the actual sealing element or part of the sealing element and it is conceivable, at least for a porous dielectric element that monitors the sealing tightness, to arrange said element independent of the sealing element at a location in the sealing system where a leakage can be recorded optimally.

If the objective is to monitor the ageing of the material of the actual sealing element, one would use the material of the sealing element as material for the dielectric element.

Generally, the element is formed by a capacitor arrangement comprised of two electrode layers and a center layer of dielectric material. The dielectric material itself can be relatively small with a thickness of preferably 10 μm and a surface area of 5 mm². Preferably, the dimensions are established so as to obtain a capacity of 1 to 1000 pF, preferably of about 100 pF, which is of advantage from a measuring technique standpoint.

In industrial plant construction, the sealing of gaseous fluids (gaseous sealing fluid such as radon, toluene, methane, water vapor) plays a significant role, and the operating temperatures can be up to 500° Celsius. The dielectric function, however, is clearly dependent on the temperature. The reason is that the basic molecular charge transport processes as well as the actual relaxation processes depend on the temperature in a manner that is characteristic for the respective system. To assess the state of the sealing system, it is therefore necessary to take the respective temperature of the sealing system into account as well.

The modification of the invention is therefore proposed for sealing systems with varying operating temperatures to measure the respective temperature of at least one sealing element and take it into account in the evaluation of the measured complex dielectric function.

This can take place, for example, by performing appropriate reference measurements at at least two different temperatures in the possible operating temperature range, and by comparing the current measuring result at the current temperature to the reference measurement at the closest temperature.

However, it is also possible to derive a temperature-corrected measuring result from the current measuring result and the current temperature and/or to derive a temperature-corrected form parameter from the determined form parameter and the current temperature.

As explained above, the dielectric characteristics of the dielectric element undergo practically no changes during normal operation of the sealing system (aside from ageing effects). However, the adsorption of gases and even more so of fluids, as a result of leakages in the sealing system, result in drastic changes of the dielectric function. Said dielectric adsorption effect can be optimized with the suitable selection of the nano-porous material and with the appropriate preparation of its inner surface areas. The inner surface areas can be optimized for entrainment of sealing fluid or of components of the same, for example the inner surface areas can be rendered hydrophilic in the sealing fluid containing water or water vapor. The other way around, it is also possible to minimize the influence of the penetration of ambient atmosphere or of components of the ambient atmosphere on the respective dielectric element by preparing the inner surface areas of said dielectric element for the lowest possible adsorption. For example, the penetration of water vapor from the ambient atmosphere into the dielectric element is often disadvantageous because it leads to changes in the dielectric function. In this case, one would render the inner surface areas hydrophobic.

Finally, it is of a special advantage with respect to the detection sensitivity if dielectric elements are used which are welded into the enclosing sealing element under vacuum. In intact sealing systems, the inner surface areas are therefore essentially free of entrainment molecules. The dielectric function measured in this case is therefore clearly different from the dielectric function after a leakage caused by the entrainment of fluid molecules, especially since they are practically suctioned into the dielectric element by the hydrostatic negative pressure.

The invention also relates to a sealing system having at least one dielectric element to perform the method as described above, as well as a sealing system having at least one dielectric element in form of a capacitor element having a center layer of a dielectric material with an electrode layer on both sides, with the center layer being preferably formed by a porous material. In the latter case, it is also possible to measure only the capacity or conductivity to determine a leakage.

For the reasons stated above, the dielectric element of the sealing system in accordance with the invention is preferably welded in under vacuum. The vacuum-tight casing of the dielectric element is developed to permit a passage of the fluid to be sealed in case of a leakage of the sealing system.

The simplest way to ensure the latter requirement is to weld the dielectric element to the actual sealing element, which is readily possible when standard sealing materials such as Teflon are used.

To perform the measurement of the current temperature of the sealing system, which was already discussed earlier, said sealing system shall be provided with at least one temperature sensor, preferably in form of a platinum film resistance, which is best integrated into the dielectric element.

The invention is explained in the following with preferred embodiments by means of the illustration.

Shown are:

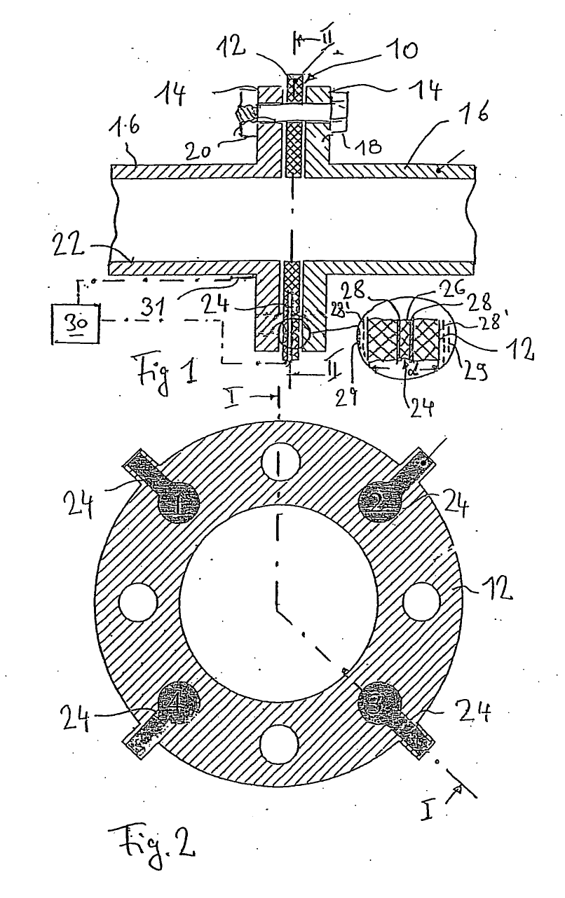

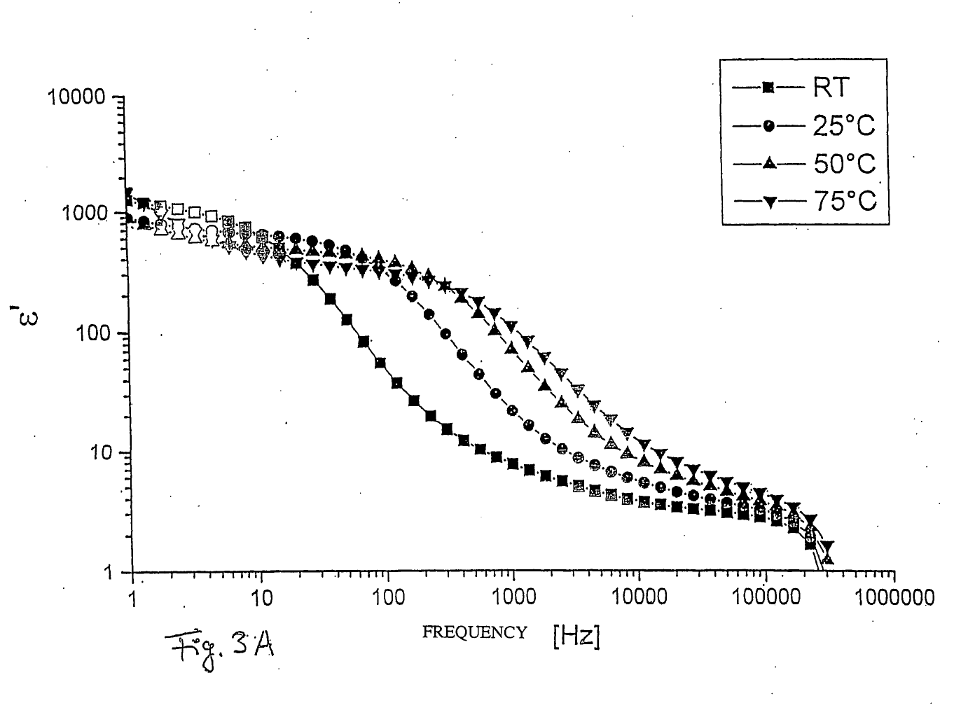

FIG. 1 a simplified longitudinal section through a pipe-joint with a sealing system in accordance with the invention (cut according to line I-I in FIG. 2);

FIG. 2 a section according to line II-II in FIG. 1;

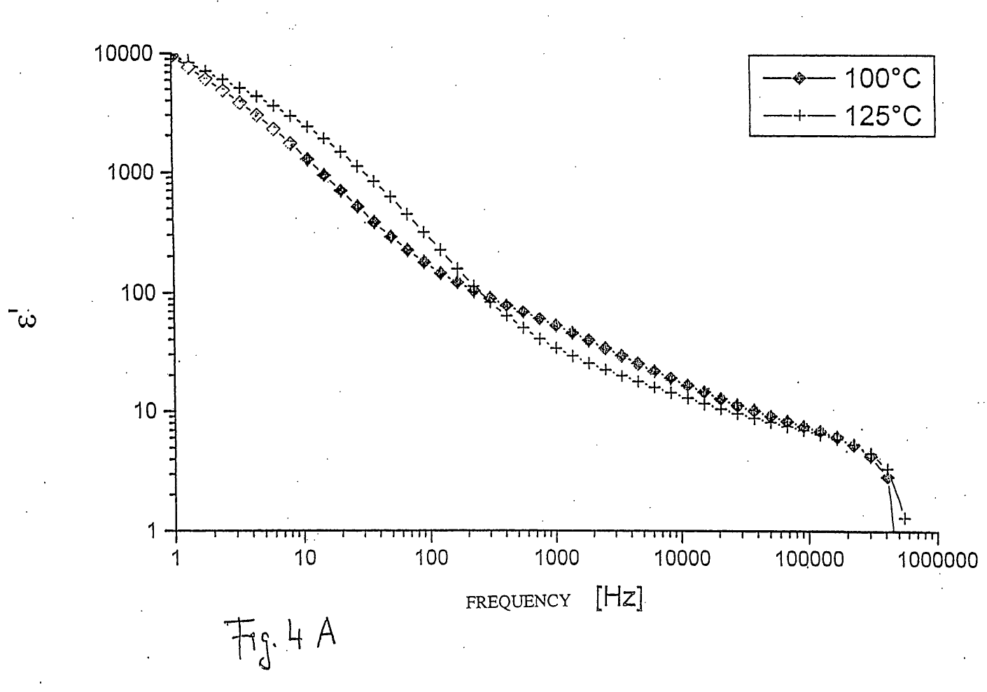

FIGS. 3A and 3B the frequency response curve of ε′ and/or ε″ of a dielectric material of aramide fibers impregnated with PTFE dispersion in the initial state as well as after intermediate heating to 25° Celsius, 50° Celsius and 75° Celsius;

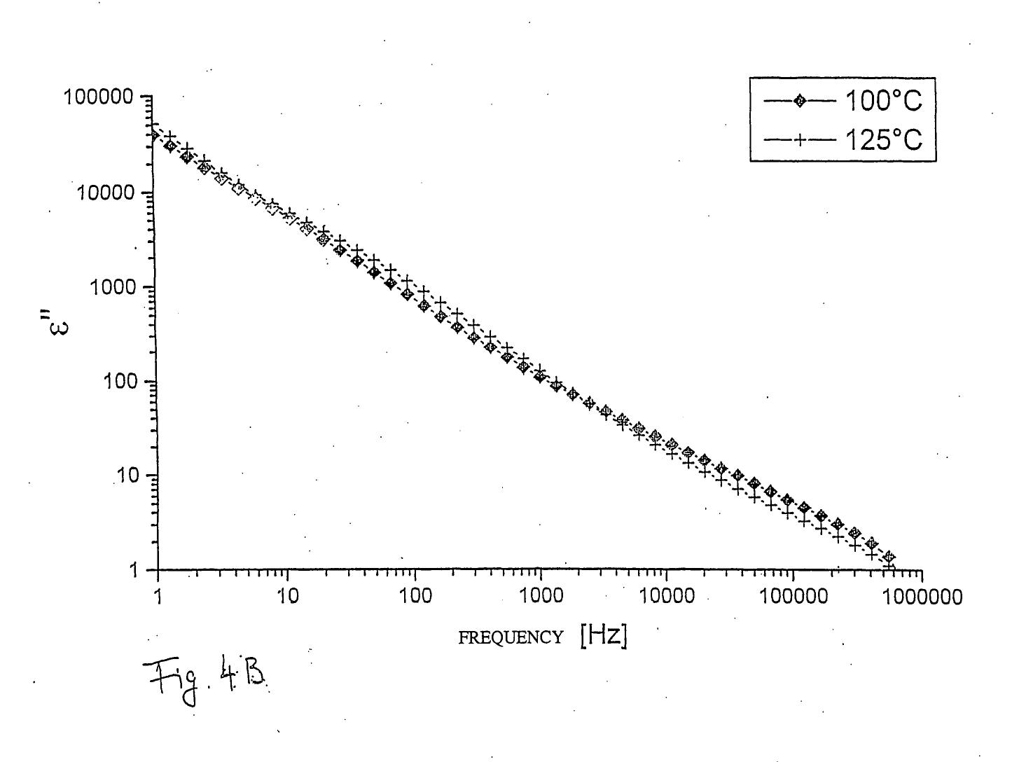

FIGS. 4A and 4B the frequency response curve of ε′ and/or ε″ on the same material, but after intermediate warming to 100° Celsius and 125° Celsius;

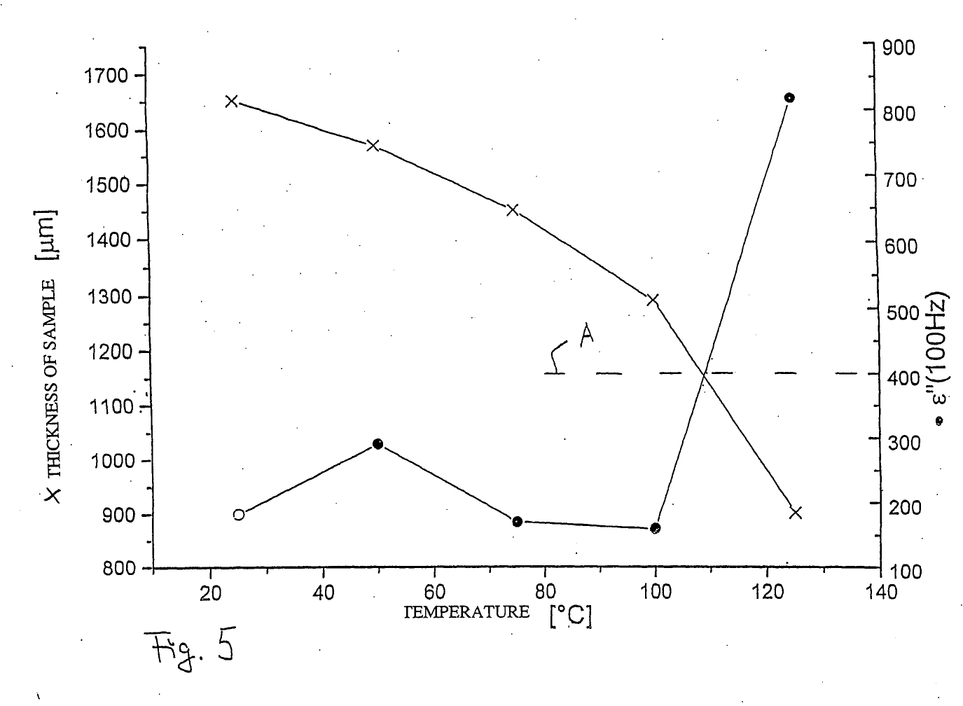

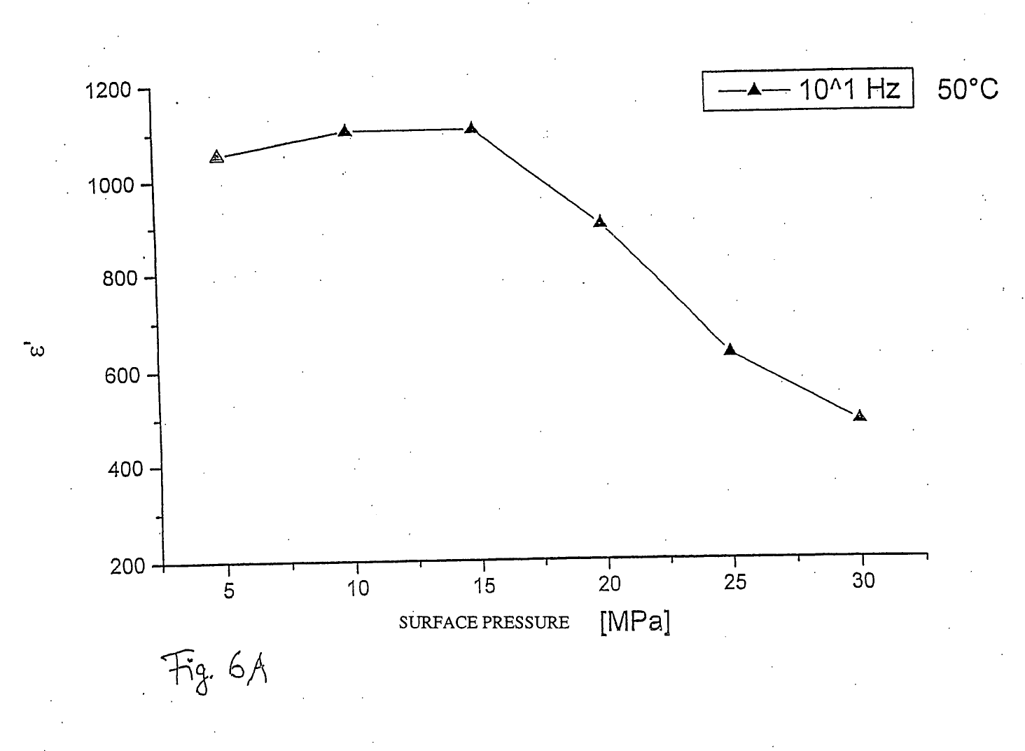

FIG. 5 a composite representation of the heating dependency of ε′ at 100 Hz and the temperature dependency of the simultaneously measured sample thickness obtained from FIG. 3A to 4B;

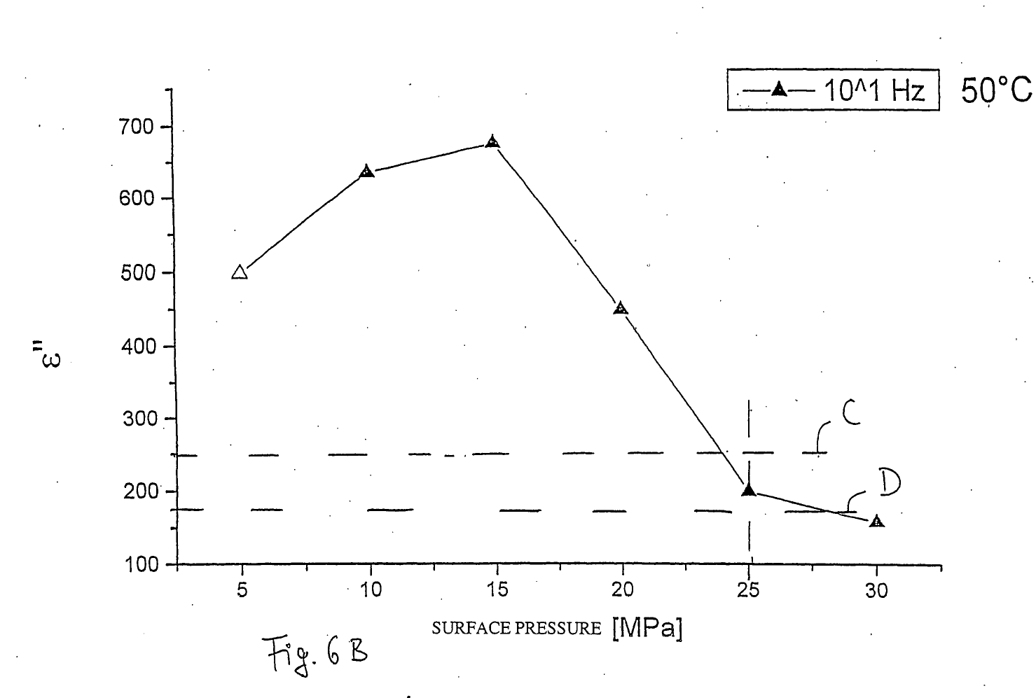

FIGS. 6A and 6B the surface area pressure dependency of ε′ and/or ε″ at 10 kHz of the same sample material after intermediate heating to 50° Celsius;

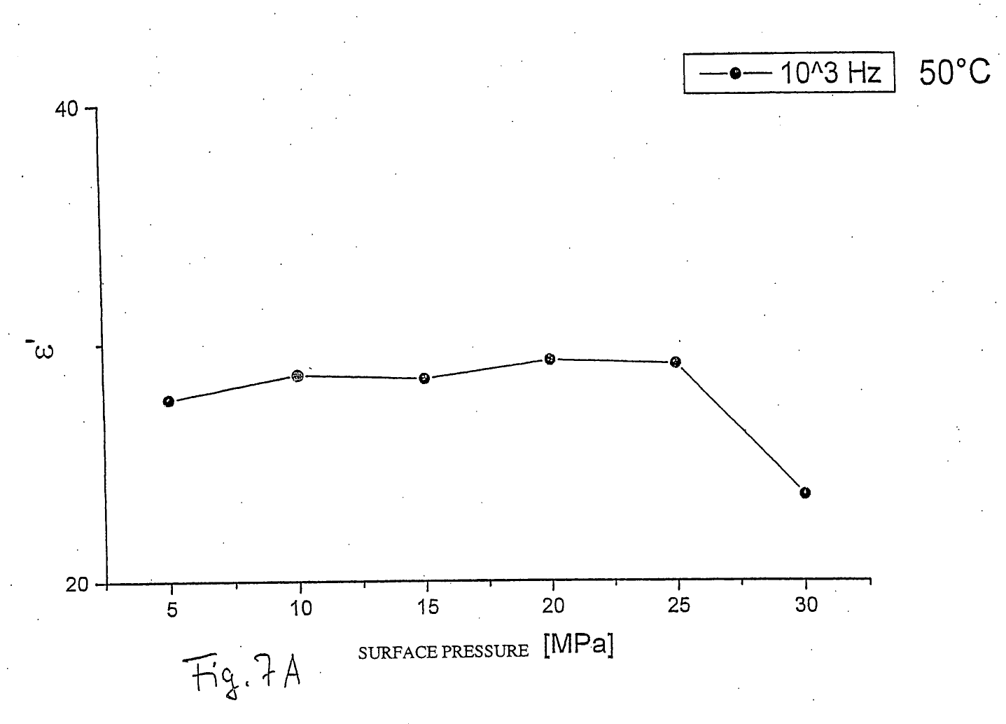

FIGS. 7A and 7B the surface area pressure dependency of ε′ and/or ε″ at 1 kHz of the same sample material after intermediate heating to 50° Celsius;

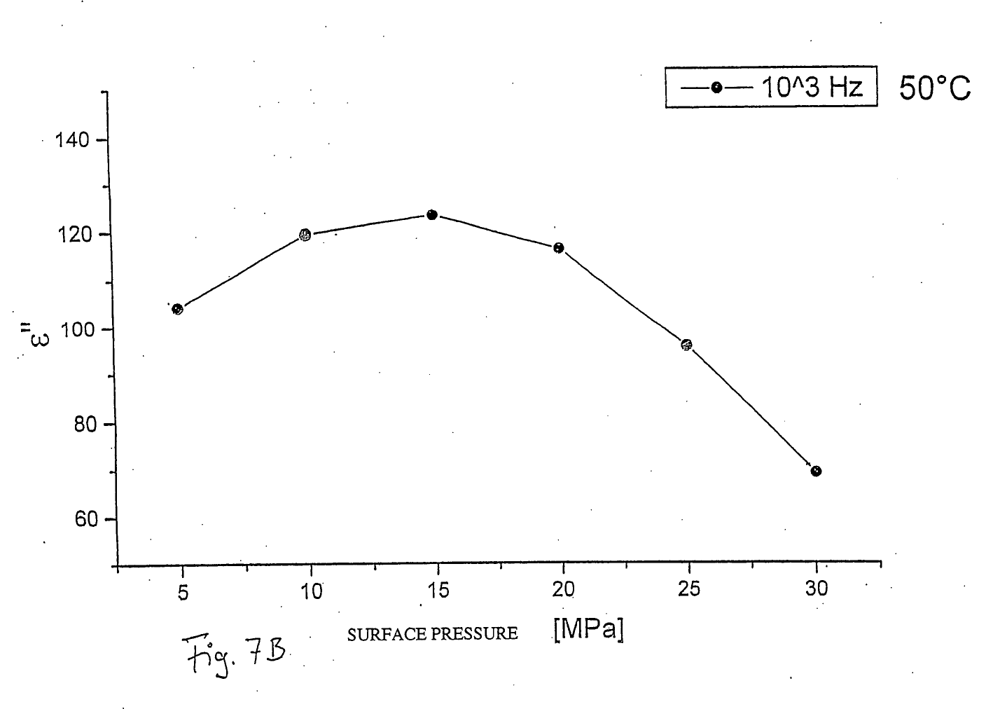

FIGS. 8A and 8B the surface area pressure dependency of ε′ and/or ε″ at 100 kHz of the same sample material after intermediate heating to 50° Celsius;

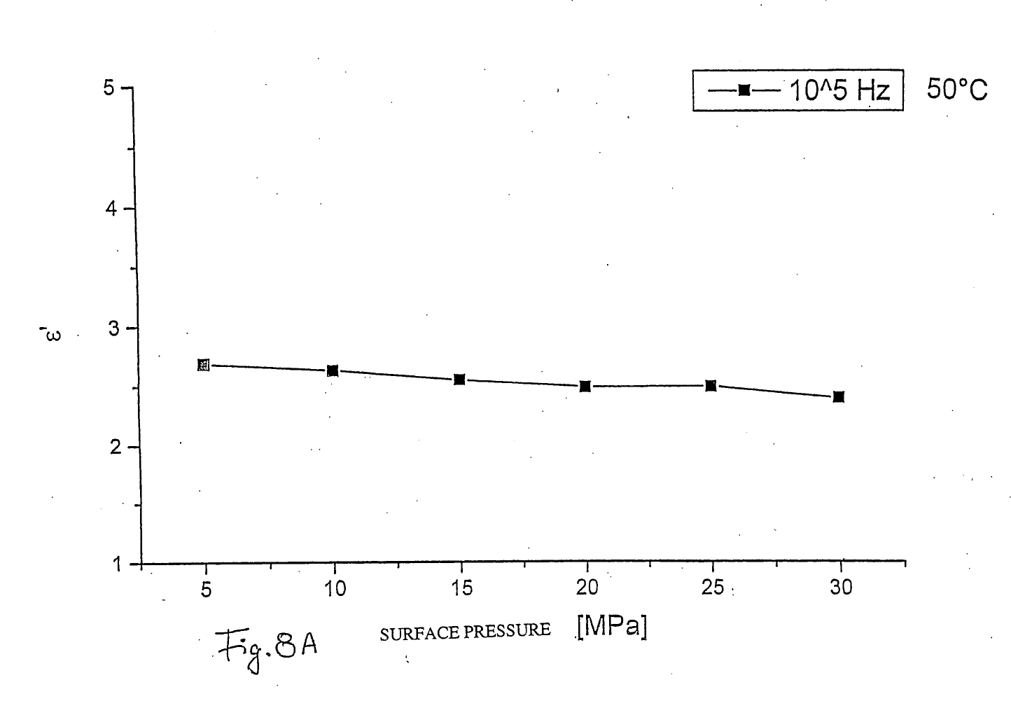

FIG. 9 a section similar to FIG. 1 but with porous dielectric material of the dielectric element (section according to line IX-IX in FIG. 10);

FIG. 10 a section according to line X-X in FIG. 9;

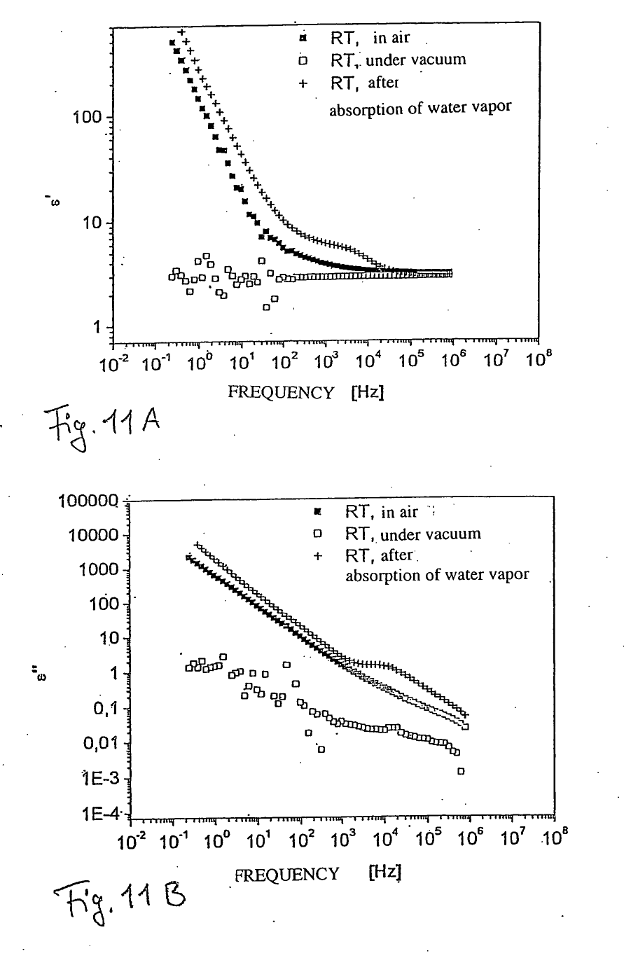

FIG. 11A and 11B the frequency response curve of ε′ and/or ε″ of sol-gel glasses (10 mm diameter, thickness 0.16 mm) under vacuum, under ambient air as well as after water vapor adsorption, at room temperature respectively;

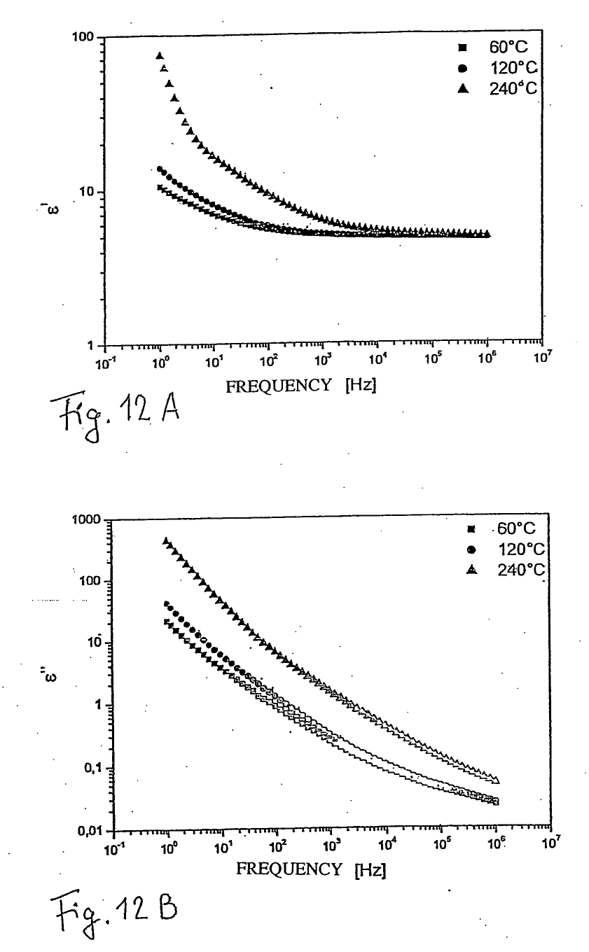

FIG. 12A and 12B the frequency response curve of ε′ and/or ε″ of PALL glass fiber filter bodies under vacuum at 60° Celsius, 120° Celsius and 140° Celsius;

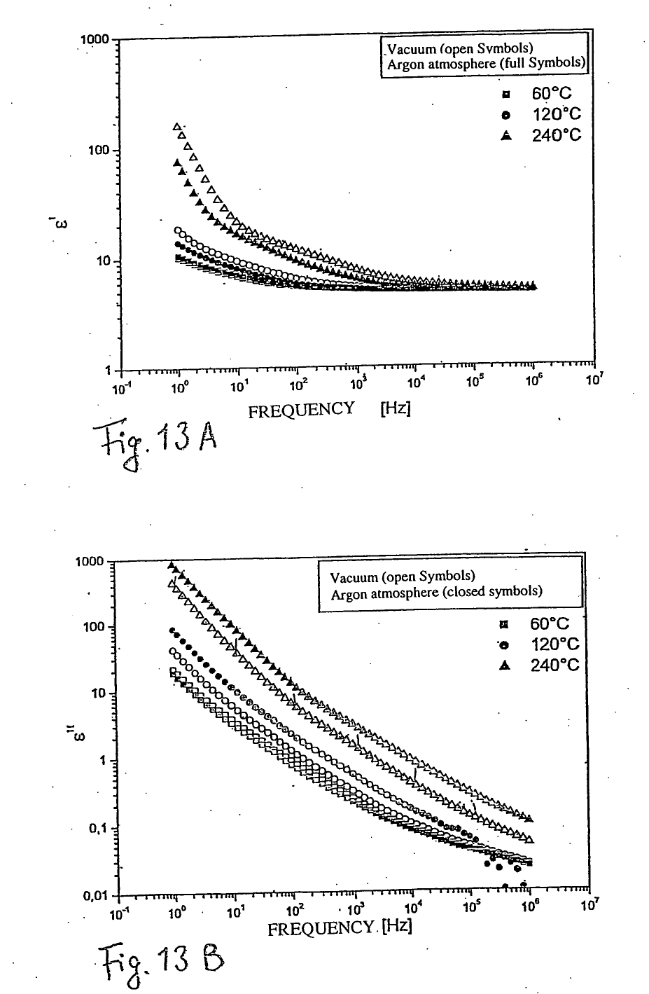

FIG. 13A and 13B the frequency response curve of ε′ and/or ε″ of the same material as in FIG. 12A and 12B at the same temperatures under vacuum as well as additionally in an argon atmosphere, and

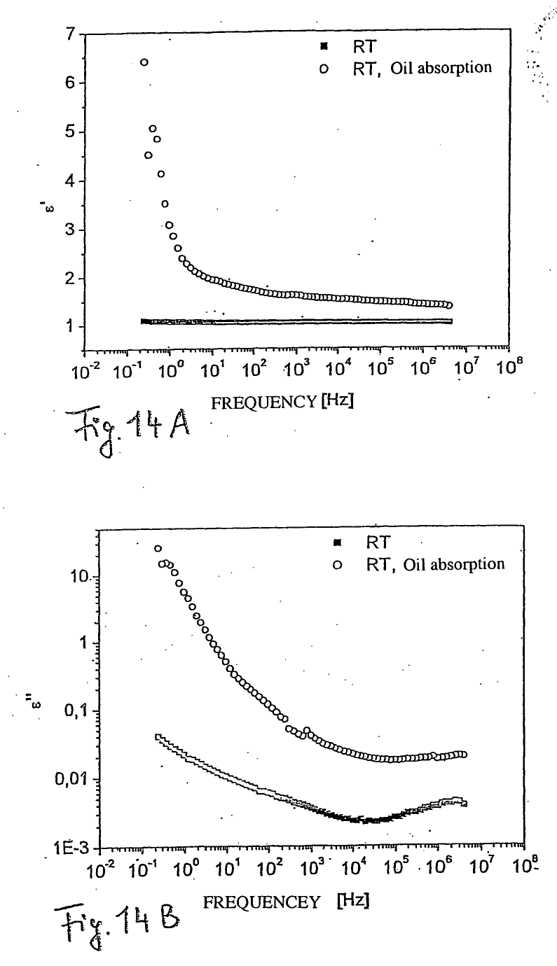

FIG. 14A and 14B the frequency response curve of ε′ and/or ε″ of a polycarbonate film (10 mm diameter, 0.01 mm thickness) at room temperature before and after oil adsorption.

FIG. 1 and 2 show a schematic representation of a sealing system 10 in accordance with the invention. It comprises an annular sealing element 12 that is inserted between two ring flanges 14 at the face ends of two pipes 16. The flanges 14 as well as the sealing element 12 have four passages, for example, which are distributed over the periphery of the circle and located on the same diameter and align during assembly to accommodate corresponding flange assemblies (screw 18, nut 20). A uniform tightening of the four screw assemblies presses the sealing element 12 together between the flanges 14 to seal the interior space 22 of the pipe toward the outside, i.e., to prevent any escape of gaseous or liquid fluid (sealing fluid) to the outside.

A total of four measuring probes in form of dielectric elements 24 are inserted into the sealing element 12; in the shown example, they are inserted into the interior of the sealing element 12 so as not to impair the sealing properties of said sealing element. Each sealing element is comprised of a center layer 26 of dielectric material as well as two electrode layers 28 on both sides of the center layer 26. Said electrode layers are connected electrically to a measuring- and evaluation unit 30, which is indicated only schematically in FIG. 1. The measuring- and evaluation unit 30 applies corresponding electromagnetic alternating fields to the electrode layers 28 to measure the dielectric function of the dielectric material of the center layer 26 in a broad frequency range. A great number of commercial measuring methods and measuring devices are available for this purpose (see, for example, the already cited chapter “Broadband dielectric measurement techniques” in “Broadband dielectric spectroscopy”, F. Kremer, A. Schönhals (Editors), published by Springer Publishing, Berlin, 2002.

Instead of a dielectric element 24 embedded into the sealing element 12, it is also possible to insert a dielectric element having a center layer that is formed by the actual sealing element 12, and having a electrode layers 28′ (indicated in dashes in FIG. 1) at the side faces of said sealing element 12, if applicable with an external cover film 29.

The measuring result shown in FIGS. 3 to 8B were obtained with the help of a “dielectric spectrometer” by Novocontrol, Hundsangen, Germany. The dielectric material of the center layer 26, which corresponded to the sealing material of the sealing element 12 in this embodiment, was comprised of aramide fibers that were impregnated with a PTFE dispersion. The dimensions of the dielectric element 24 according to FIG. 1 and 2 are not according to scale. Sufficient sensitivity is already obtained with dielectric elements having an electrode surface area of 5 mm² and a total thickness of the dielectric element of approx. 10 μm. These dimensions result in a capacity of approx. 100 pF, which is easy to measure.

To determine the influence of an ageing of the sealing material on the dielectric function, ε′ and/or ε″ were measured in a frequency range between 1 Hz and 500 kHz, each time at a mechanical surface pressure of 25 MPa. The measuring points marked with a rectangle were obtained in the first measurement. The remaining measurements were taken after intermediate heating to 25° Celsius 50° Celsius, 75° Celsius, 100° Celsius and 125° Celsius respectively in continued clamped state and subsequent cooling to approximately room temperature.

It is shown that the dielectric spectra are characterized in ε′ and ε″ by a stage that moves to higher frequencies with increasing intermediate heating temperature. This type of dependency is typical for a relaxation process. The PTFE micelles disintegrate from a temperature of approx. 100° Celsius on. Consequently, the stage in ε′ and ε″ disappears (FIG. 4A and 4B). However, the electrical conductivity that is determined by the increase in ε″ toward lower frequencies increases by approximately 1 to 2 orders of magnitude. At the same time, the ionic charge transport and the resulting electrode polarization effects an increase of ε′ on the low frequency side.

When comparing the decrease of the sample thickness (=thickness d of the sealing element 12 according to FIG. 1) applied in FIG. 5 to the surface pressure of 25 MPa with increasing temperature at the measurements, there is a strong decrease starting at approximately 100° Celsius. This is apparently the result of a collapse of the visco-elastic restoring force of the polymer material at the thermally induced degradation of the micelle structure. At the same time, the value of ε′ increases steeply at 100 Hz.

This leads to the conclusion that the sealing material is no longer functionally efficient after intermediate heating to over 100° Celsius, which corresponds to a value of ε′ measured at 100 Hz clearly above a limit value A of 400, for example.

One can now readily assume that an ageing of the sealing material, which was simulated in time-lapse by the temper program, will have the same effect on ε″, measured at 100 Hz.

Thus, one would select ε″ as form parameter, measured at 100 Hz, for the specific sealing material used here, and measure said form parameter continually during the operation of the sealing system and compare it to the limit value A. If the limit value A is exceeded, the sealing element must be replaced.

Depending on the composition of the sealing material being used, it is also possible to select other form parameters, or combinations of at least two form parameters.

An example is the measurement of the dielectric loss with materials having a visible peak in ε″, such as vulcanized hard rubber, at frequencies that are generally greater than 1 kHz.

For a sealing material made of the aromatic polyamide fibers (such as armide [sic] fibers) embedded into the nitrile rubber, the following combination has proven useful:

1^{st} form parameter: Slope the real part at lower frequencies preferably <100 Hz; 2^{nd} and 3^{rd} form parameter: absolute values of the real part and the imaginary part at high frequencies, preferably >1 kHz.

The corresponding limit values are again determined by reference measurements with simulation of the material ageing.

In addition to the ageing of the state parameters of the sealing system, the correct position of the sealing system can be determined as an additional state parameter. To corroborate this, pressure-dependent measurements were performed according to FIG. 6B, b for ε′ and ε″ with the frequencies 10 Hz, 1 kHz and 100 kHz, specifically after a one-time intermediate heating to 50° Celsius, to ensure a settling of the sealing system. The result is a more or less strong surface pressure dependency, which is most pronounced for ε″ at 10 Hz according to FIG. 6B.

This effect is therefore well suited for reviewing the correct assembly position by comparing the measuring values for ε″ up to 10 Hz provided by the four, for example, dielectric elements 24 distributed across the periphery of the sealing element 12. If the measuring values deviate from the given measurement, it can be concluded that the assembly position is skewed. Alternately, limit values specific to the material can be introduced, such as the limit values C and D in FIG. 6B at a target surface pressure of 25 MPa, for example. If these limit values are exceeded by one or the other dielectric element 24, one would conclude an assembly error.

Another state parameter of the sealing system which can be recorded in accordance with the invention is the seal-tightness of the sealing system. Here the measuring probe is again the dielectric element. In this case, the dielectric element is made of a material that is capable of taking up the fluid to be sealed and changing its dielectric function accordingly. For one, this material may be the sealing material of the sealing element. Alternately, porous dielectric material can also be used, with the available materials having an extremely high interior surface area to take up correspondingly large quantities of the fluid. Such materials with capillary diameters in the pm-range or nm-range have interior surface areas of >10 m²/g, but also of >100 m²/g. This leads to a drastic change of the entire dielectric function in a large frequency range including at the frequency <0.01 Hz (parallel flow limit). Thus, it is possible in some cases to monitor the seal-tightness with simple capacity measurements, with the dielectric element being arranged independently of the sealing element at a location of the sealing system which is well suited to record a leakage.

FIGS. 9 to 10 again indicate an embodiment only schematically. Again, a sealing system 110 is shown, which is comprised of the actual annular sealing element 112, which is pressed together between two flanges 114 in the direction of the pipe axis 123 with the help of a total of four screw assemblies (cap screw 118, nut 12). The two flanges 114 are provided at the ends of two pipes 116 facing one another. The sealing system 110 is designed to seal the interior space of the pipe 122 from the adjacent area.

In the shown embodiment, the dielectric elements 124 are again comprised of three layers, i.e., the center layer 126 of porous dielectric material and the two lateral electrode layers 128. The latter are again guided out of the sealing element 112 by electrical lines 125 indicated in FIG. 12, and joined at the outer periphery of the sealing element 112 in a schematically indicated connecting piece 140. In a manner not shown, the connecting piece 140 can be connected to a measuring- and evaluation unit (as in 30 according to FIG. 1).

The dielectric elements 124 are again not represented according to scale. They can have an electrode surface area of 5 mm² at a thickness of approx. 10 μm. This results in a capacity of approx. 100 pF, which is easy to record with measuring techniques.

The dielectric elements 124 are again installed into the sealing material of the sealing element 112 to provide a perfect sealing surface of the sealing element 112 on both of its sides.

According to FIG. 10, the dielectric elements 124 can be distributed across the periphery of the sealing element 112, and an additional staggering may be provided in the direction of the pipe axis 123 according to FIG. 9. This distribution ensures a uniform monitoring of the volume of the sealing element 112. If the fluid to be sealed penetrates the sealing element 112 at any point, said fluid will sooner or later reach one of the porous dielectric elements 124. Because of its large capillary forces (relative to the fluid used), said porous dielectric element will take up a relatively large quantity of fluid, resulting in a correspondingly drastic change of its dielectric function, including its capillarity. Thus, if the sealing becomes fragile or if individual cracks occur, this can be determined dependably by measuring the dielectric function and/or the capacity.

Here again, one would determine a suitable form parameter depending on the material being used, and establish a suitable limit value for said form parameter by performing reference measurements and increasing the pressure until leakage occurs.

The porous dielectric material, if applicable, may be the same substance that is used for the actual sealing element because some materials, especially PTFE, exist as a compact (non-porous) material as well as in porous form.

The FIGS. 11A and B show how the dielectric function [TrNote: verb missing] depending on the degree of a water vapor absorption in a micro-porous dielectric material available from Schott in Mainz, Germany under the designation “Sol-Gel-Glas”. The sample was 0.16 mm thick with a glass diameter of 10 mm and a pore diameter of 7.5 nm. The measurement was performed at room temperature (RT). It is shown that after water vapor absorption at frequencies below approx. 5×10⁴ Hz, ε′ is clearly higher in comparison to a measurement in ambient atmosphere and retains the characteristic upward slope towards lower frequencies. However, in a comparison to a measurement under vacuum, there are significantly greater differences toward lower frequencies because under vacuum, ε′ is approximately constant over a frequency range between 10⁶ and 10² Hz and scatters up to 0.1 Hz around said constant value toward lower frequencies.

ε″ also results in a not too large, but clearly visible upward shift when first measured under atmospheric conditions (relative air humidity ≦30%) as well as after water vapor absorption (relative air humidity 100%). However, the difference is again significantly greater here when proceeding from a measurement under vacuum (i.e., absolute pressure <1 mbar).

To take advantage of this effect, the respective dielectric element is welded in under vacuum (pressure <1 mbar), preferably into the actual sealing element (see FIGS. 9, 10). This is readily possible with conventional sealing materials such as polytetrafluoroethylene (Teflon).

If, for whatever reason, the sealing system experiences a leakage, the appropriate hairline cracks also reach the dielectric elements embedded into the material of the sealing element, which practically suction in the sealing fluid (in this case water or water vapor) that penetrates into the sealing system, with the result of absorptions on the interior surface areas. The dielectric function changes drastically, as shown with the examples in FIGS. 11A and 11B.

The FIGS. 11A and 11B also allow the conclusion of suitable limit values which, when exceeded, indicate a leak in the sealing system. A monitoring circuit then issues an alarm so that counter measures can be taken in sufficient time.

The FIGS. 12A and 12B show the clear temperature dependency of the dielectric function, with a fiber glass filter element by Pall, Life Sciences, represented by VMR International GmbH, Frankfurter Str. 133, 64293 Darmstadt, Germany being used. Said glass had a diameter of 10 mm, a thickness of 330 μm and a pore diameter of 1.0 μm. These measurements were performed under vacuum. A doubling of the starter temperature from 60° Celsius to 120° Celsius results in a slight increase of ε′ at frequencies below 100 Hz and of ε″ at frequencies below 10³ Hz. A further doubling to 240° Celsius, however, results in a clear increase of ε′ at frequencies below 10⁴ Hz as well as a general increase of ε″ in the entire frequency range.

For sealing systems operated under not nearly uniform temperatures, such as plants with gaseous sealing fluid (radon, gaseous toluene, methane and water vapor), this means that it is useful to take into account the respective current operating temperature as well.

The operating temperature can be recorded in the conventional manner with temperature sensors, for example in form of a platinum film resistance. In FIG. 1, a temperature sensor 31 of this type is indicated on the external side of the piping 16 in the area of the ring flange 14, which, for example, is connected electrically to the measuring- and evaluation sensor 30. It is also conceivable to integrate the temperature sensor into the sealing element or even into the dielectric element.

To compensate for the temperature effect described above, it is also possible to take up multiple measurements at various temperatures across the operating temperature range, similar to FIG. 12A and 12B, and save them as reference measurements in the memory. During current operation, the current measurement is then compared at the current operating temperature to the reference measurement that was measured at a temperature closest to the operating temperature. If significant deviations are encountered, one could conclude that the state parameter in question has changed, i.e., for example that there is a leakage in the system or that the sealing system has aged.

However, a compensation of the temperature effect can also be achieved mathematically in the following way:

The measured temperature- and frequency dependency of the complex dielectric function can be adjusted with the following function:

[TrNote: please insert equations from page 22 of source document]

With the constants ε₀₀, A, B, λ₁, λ₂, Δε, T, α and γ, with

[TrNote: Please insert equation from page 23 of source document] describing the real and/or imaginary part. The relaxation processes are described by the so-called Havriliak-Negami function and the electrode polarization by potency laws with ω^{-λ1} and ω^{-λ2}. These adjustments can be made quickly and without any problems with the “least square method” for various temperatures to characterized the entire dielectric function in its frequency- and temperature dependency. The resulting set of data—which of course is specific to the material—can then be used to make a decision—if necessary by means of interpolation—as to whether the sealing material exhibits characteristics that deviate from the standard and indicate a leakage, chemical degradation or physical ageing. The entire method can be automated without any problems. In addition to the measuring curves according to FIGS. 12A and 12B under vacuum, the FIGS. 13A and B also show the measuring curves at the corresponding temperatures in argon atmosphere (closed symbols). They show the significance of the temperature dependency because generally a temperature increase as well as an entrainment of argon will lead to an increase of ε′ and ε″. At 60° Celsius, an argon entrainment in ε″ will result in only a small increase and in ε′ at frequencies below 10 Hz even in a slight decrease. The current measuring temperature must therefore taken into consideration in the evaluation of the measurement as described above.

Finally, the FIGS. 14A and 14B show the effect of an oil adsorption at a micro capillary poly-carbon film with a glass diameter of 10 mm and a thickness of 10 μm and a pore diameter of 0.1 μm measured at room temperature (RT). Said figures show clear changes in ε′ and ε″. Whereas ε′ remains constant across the entire frequency range prior to the oil adsorption, there is a strong upward slope toward lower frequencies after the oil adsorption. ε″ has a sinuous course prior to the oil adsorption with strong increase while maintaining the principle curve trace (drop toward lower frequencies) after oil adsorption.

Overall, an “intelligent sealing system” is obtained by recording the dielectric function in a broad frequency range, which may also include the parallel flow limit, if applicable. In particular, it is possible to dependably detect a skewed assembly position, the ageing of the sealing system, as well as leakages.

### LIST OF REFERENCE SYMBOLS

10 Sealing system
12 Sealing element
14 Ring flange
16 Piping
18 Screw
20 Screw nut
22 Interior space of piping
24 Dielectric element
26 Dielectric center layer
28 Electrode layer
28′ Electrode layer
29 Cover film
30 Measuring- and evaluation unit
31 Temperature sensor
110 Sealing system
112 Sealing element
114 Flange
116 Piping
118 Cap screw
120 Screw nut
122 Interior space of piping
123 Piping axis
124 Dielectric element
125 Electrical lines
126 Dielectric center layer
128 Electrode layer
140 Connecting piece

1-43. (canceled)

44. Method for determining at least one state parameter of a sealing system (10, 100) with at least one sealing element (12, 112) and at least one dielectric element (24, 124) containing dielectric material, with the real part and/or the imaginary part of the complex dielectric function of the dielectric element being measured, characterized in that
the dielectric material (26,126) of the dielectric element (24,124) is formed by a porous material.

45. Method in accordance with claim 44, characterized in that
the porous material has a high capillarity, preferably with an interior surface area of >10 m²/g, better yet with >100 m²/g, relative to the fluid from which the sealing system is supposed to seal.

46. Method in accordance with claim 44, characterized in that
the dielectric element (24, 124) is formed by a capacitor arrangement comprised of two electrode layers (28, 28′, 128) on both sides of a center layer (26, 126) of dielectric material.

47. Method in accordance with claim 46, characterized in that
the dielectric element (24, 124) has a thickness of less than 1 mm, preferably less than 100 μm and even better of approximately 10 μm.

48. Method in accordance with claim 47, characterized in that
the dielectric element (24, 124) has a capacity of 1 pF to 1000 pF, better yet of approximately 100 pF.

49. Method in accordance with claim 44, characterized in that
a dielectric element is used which has inner surface areas prepared for the largest possible entrainment of the sealing fluid or of components of the same.

50. Method in accordance with claim 44, characterized in that
a dielectric element is used that has inner surface areas prepared for the smallest possible entrainment of an ambient fluid or of with components of the same.

51. Method in accordance with claim 49, characterized in that
the inner surface areas are rendered hydrophobic or hydrophilic.

52. Method in accordance with claim 44, characterized in that
the respective temperature of the at least one sealing element is measured and taken into account in the evaluation of the measured complex dielectric function.

53. Method in accordance with claim 52, characterized in that
reference measurements are performed in the possible operating temperature range of the sealing system at at least two different temperatures, and that the current measuring result at the current temperature is compared to the reference measurement at the closest temperature to the current temperature.

54. Method in accordance with claim 52, characterized in that
a temperature-corrected measuring result is derived from the current measuring result and the current temperature.

55. Method in accordance with claim 52, characterized in that
a temperature-corrected form parameter is derived from the form parameter and the current temperature.

56. Method in accordance with claim 44, characterized in that
measuring is performed at least one frequency of >10⁻² Hz.

57. Method in accordance with claim 56, characterized in that
the at least one frequency is in a frequency range of 0.1 Hz to 10 MHz, preferably 100 Hz to 100 kHz.

58. Method in accordance with claim 44, characterized in that
a characteristic frequency response curve of the real part and/or the imaginary part of the dielectric function is determined by measuring the real part and/or the imaginary part of the complex dielectric function of the dielectric element at different frequencies, with the measurements being performed at at least two, preferably at least ten and even better at at least 30 different frequencies.

59. Method in accordance with one of the claim 58, characterized in that
at least one form parameter of the frequency response curve is determined.

60. Method in accordance with claim 59, characterized in that
the form parameter is an absolute value or an increase or a curvature of the frequency response curve at a given frequency.

61. Method in accordance with claim 59 characterized in that
the form parameter is the frequency position or the amplitude of a characteristic segment of the frequency response curve.

62. Method in accordance with claim 61, characterized in that
the characteristic segment is a stage or a peak.

63. Method in accordance with claim 59, characterized in that
at least one of the form parameters is the increase of the real part at lower frequencies, preferably ≦100 Hz.

64. Method in accordance with claim 59, characterized in that
at least one of the form parameters is the absolute value of the real part or the imaginary part at high frequencies, preferably ≧1 kHz.

65. Method in accordance with claim 59, characterized in that
the at least one form parameter is the absolute value of the imaginary part at a frequency between 10 Hz and 1 kHz, preferably of approximately 100 Hz.

66. Method in accordance with claim 59, characterized in that
the at least one form parameter is the surface area below a peak of the frequency response curve of the imaginary part.

67. Method in accordance with claim 59, characterized in that
the at least one form parameter is the quotient from the absolute values of the imaginary part and the real part, preferably at a frequency of ≦1 kHz.

68. Method in accordance with claim 44, characterized in that
a dielectric element (24, 124) is provided at a plurality of places, preferably at three or four places, in the sealing element (12, 112) and the real part and/or the imaginary part of the dielectric function is/are measured.

69. Method in accordance with claim 68, characterized in that
the measuring results obtained in a plurality of places are compared and in case of a deviation that exceeds a given measure a skewed assembly position of the sealing system (10, 110) is inferred.

70. Method in accordance with claim 44, characterized in that
the current measuring result is compared to a reference measurement on a functionally efficient sealing element (12, 112) and in case of any deviation that exceeds a given measure or exceeds or falls below a given limit value it is inferred that the current sealing element (12, 112) is not functionally efficient.

71. Method in accordance with claim 70, characterized in that
the reference measurement is performed on the sealing element (12, 112) of the sealing system (10, 110), preferably after the sealing system has been assembled, and that corresponding measurements are performed and compared to the reference measurement for the continuous monitoring of the sealing system.

72. Method in accordance with claim 70, characterized in that
in order to determine the given measure of the permissible deviation and/or the given limit value, at least one stress test measurement, preferably with intermediate sample heating steps, is performed on a sample of the dielectric material that is also used for the sealing system (10, 110).

73. Method in accordance with claim 44, characterized in that
the dielectric element (24, 124) is the sealing element (12, 112) or part of the sealing element (12, 112) of the sealing system (10, 110).

74. Sealing system (10, 110) having at least one dielectric element (24, 124) in form of a capacitor element comprised of a center layer (26, 126) of dielectric material having one each electrode layer (28, 28′, 128) on each side and with a measuring- and evaluation unit (30) connected to the at least one dielectric element (24, 124) characterized in that
the center layer (126) is formed of porous material.

75. Sealing system (110, 110) in accordance with claim 74, characterized in that the dielectric element (24, 124) is welded in under vacuum.

76. Sealing system in accordance with claims 74, characterized in that
the dielectric element (24, 124) is embedded in a sealing element of the sealing system.

77. Sealing system in accordance with claim 76, characterized in that
the dielectric element (24, 124) is welded to the sealing element.

78. Sealing system in accordance with claim 74, characterized in that
it has at least one temperature sensor.

79. Sealing system in accordance with claim 78 characterized in that
the at least one temperature sensor is formed by a platinum film resistance.

80. Sealing system in accordance with claim 78, characterized in that
the temperature sensor is integrated into the dielectric element.

81. Sealing system (10, 110) in accordance with claim 74, characterized in that
the measuring- and evaluation unit (30) is adapted to determine a characteristic frequency response curve of the real part and/or the imaginary part of the dielectric function by measuring the real part and/or the imaginary part of the complex dielectric function of the dielectric element at different frequencies.
